(19) United States
(12) Patent Application Publication
(10) Pub. No.: US 2024/0409430 A1
(43) Pub. Date: Dec. 12, 2024

(54) HAFNIUM PRECURSORS AND RELATED METHODS

(71) Applicant: ENTEGRIS, INC., Billerica, MA (US)

(72) Inventors: Juan Valdez, Copperas Cove, TX (US); Michael Watson, Leander, TX (US); Scott L. Battle, Cedar Park, TX (US); Matthew W. Calhoun, Burnet, TX (US); Benjamin R. Garrett, Leander, TX (US); Wesley W. Goggans, Meadowlakes, TX (US)

(21) Appl. No.: 18/679,227

(22) Filed: May 30, 2024

Related U.S. Application Data
(60) Provisional application No. 63/471,472, filed on Jun. 6, 2023.

(51) Int. Cl. C01G 27/04; C23C 16/08; C23C 16/448

(52) U.S. Cl. CPC C01G 27/04; C23C 16/08; C23C 16/448

(57) ABSTRACT

A precursor vessel comprises a hafnium halide precursor. The hafnium halide precursor comprises less than 1 ppm of at least one impurity. The at least one impurity comprises at least one of a titanium contaminant, a chromium contaminant, an aluminum contaminant, an iron contaminant, or any combination thereof. Related systems and related methods are also provided, including, for example and without limitation, systems for delivery of vapor precursors, methods for purifying a precursor, and the like.

### CROSS-REFERENCE TO RELATED APPLICATIONS

This application claims the benefit under 35 USC 119 of U.S. Provisional Patent Application No. 63/471,472, filed Jun. 6, 2023, the disclosure of which is hereby incorporated herein by reference in its entirety.

### FIELD

The present disclosure relates to hafnium precursors with high purity, and related systems and methods.

### BACKGROUND

The presence of impurities in precursors used for semiconductor fabrication results in defects and undesirable process variability. Providing precursors with sufficiently low levels of impurities remains an ongoing challenge.

### SUMMARY

Some embodiments relate to a system comprising a precursor vessel and a vapor deposition apparatus. In some embodiments, the vapor deposition apparatus is provided in fluid communication with an outlet of the precursor vessel. In some embodiments, the precursor vessel comprises a solid hafnium halide precursor. In some embodiments, the solid hafnium halide precursor comprises at least one of hafnium (IV) chloride (HfCl₄), hafnium (IV) bromide (HfBr₄), hafnium (IV) iodide (Hfl₄), hafnium (IV) fluoride (HfF₄), hafnium (III) chloride (HfCl₃), hafnium (III) bromide (HfBr₃), hafnium (III) iodide (Hfl₃), hafnium (III) fluoride (HfF₃), or any combination thereof. In some embodiments, the solid hafnium halide precursor comprises less than 1 ppm of at least one impurity. In some embodiments, the at least one impurity comprises at least one of a titanium contaminant, a chromium contaminant, an aluminum contaminant, an iron contaminant, or any combination thereof.

Some embodiments relate to a precursor vessel. In some embodiments, the precursor vessel comprises a solid hafnium halide precursor. In some embodiments, the solid hafnium halide precursor comprises at least one of hafnium (IV) chloride (HfCl₄), hafnium (IV) bromide (HfBr₄), hafnium (IV) iodide (Hfl₄), hafnium (IV) fluoride (HfF₄), hafnium (III) chloride (HfCl₃), hafnium (III) bromide (HfBr₃), hafnium (III) iodide (Hfl₃), hafnium (III) fluoride (HfF₃), or any combination thereof. In some embodiments, the solid hafnium halide precursor comprises less than 1 ppm of at least one impurity. In some embodiments, the at least one impurity comprises at least one of a titanium contaminant, a chromium contaminant, an aluminum contaminant, an iron contaminant, or any combination thereof.

Some embodiments relate to a method for purification. In some embodiments, the method comprises one or more of the following steps: obtaining a first vessel comprising a solid reagent, the solid reagent comprising a hafnium halide and at least one impurity; vaporizing at least a portion of the solid reagent to produce a first vapor comprising a hafnium halide vapor and at least one impurity vapor; flowing at least a portion of the hafnium halide vapor and at least a portion of the at least one impurity vapor to a second vessel; condensing at least a portion of the hafnium halide vapor in the second vessel to separate at least a portion of the hafnium halide vapor from the at least one impurity vapor; and removing at least a portion of the at least one impurity vapor from the second vessel to obtain a hafnium halide precursor.

### DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 is a flowchart of a method for purification, according to some embodiments.

FIG. 2 is an embodiment of a system for purification.

FIG. 3 is a chart showing purity levels by temperature.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

Some embodiments relate to high purity and ultrahigh purity hafnium halide precursors, and related systems and methods. The hafnium halide precursors disclosed herein have low impurity levels. The hafnium halide precursors disclosed herein have impurity levels that have previously not been attainable, for example, by conventional purification methods. At least one advantage of the hafnium halide precursors disclosed herein is that, when the hafnium halide precursors are supplied to a downstream tool (e.g., a tool used in semiconductor fabrication or other similar processes), the hafnium halide precursor, upon being vaporized, is supplied to the tool at a controllable constant flow rate, without appreciable spikes or variations in flow rate. These shall not be limiting as these and other benefits will become apparent upon review of the disclosure provided herein.

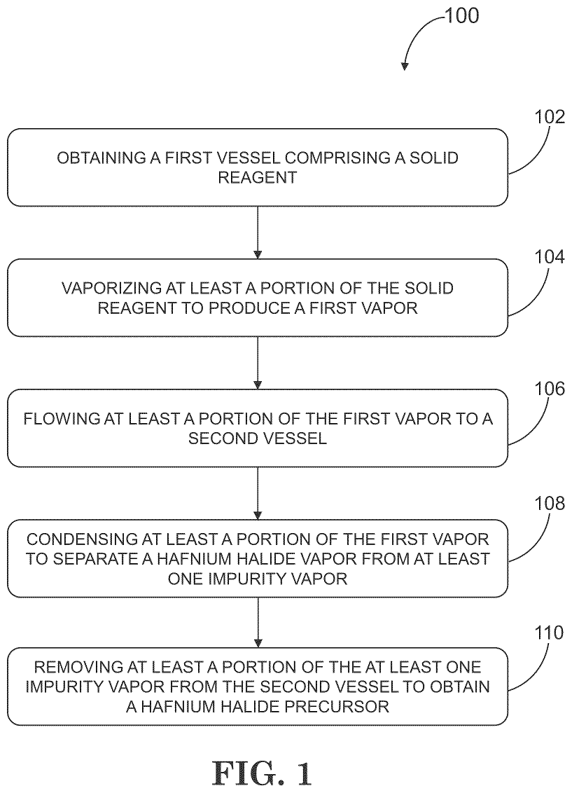

FIG. 1 is a flowchart of a method of purification 100, according to some embodiments. As shown in FIG. 1, the method of purification 100 may comprise one or more of the following steps: obtaining 102 a first vessel comprising a solid reagent, the solid reagent comprising a hafnium halide and at least one impurity; vaporizing 104 at least a portion of the solid reagent to produce a first vapor comprising a hafnium halide vapor and at least one impurity vapor; flowing 106 at least a portion of the hafnium halide vapor and at least a portion of the at least one impurity vapor to a second vessel; condensing 108 at least a portion of the hafnium halide vapor in the second vessel to separate at least a portion of the hafnium halide vapor from the at least one impurity vapor; and removing 110 at least a portion of the at least one impurity vapor from the second vessel to obtain a hafnium halide precursor.

In some embodiments, the method of purification 100 comprises obtaining 102 a first vessel comprising a solid reagent.

The solid reagent may comprise a hafnium halide. The hafnium halide may comprise at least one of a hafnium (IV) halide, a hafnium (III) halide, or any combination thereof. For example, in some embodiments, the hafnium halide comprises at least one of hafnium (IV) chloride (HfCl₄), hafnium (IV) bromide (HfBr₄), hafnium (IV) iodide (Hfl₄), hafnium (IV) fluoride (HfF₄), hafnium (III) chloride (HfCl₃), hafnium (III) bromide (HfBr₃), hafnium (III) iodide (Hfl₃), hafnium (III) fluoride (HfF₃), or any combination thereof. Under the conditions of the first vessel, the solid reagent may be present as a solid; however, it will be appreciated that the conditions of the first vessel may vary such that the reagent is present in another phase, such as, for example, at least one of a gas phase, a vapor phase, a liquid phase, a solid phase, or any combination thereof.

The solid reagent may comprise at least one impurity. The at least one impurity may comprise at least one of a titanium contaminant, a chromium contaminant, an aluminum contaminant, an iron contaminant, or any combination thereof. As used herein, the term “titanium contaminant” refers to a substance other than the hafnium halide, wherein the substance other than the hafnium halide comprises titanium. As used herein, the term “chromium contaminant” refers to a substance other than the hafnium halide, wherein the substance other than the hafnium halide comprises chromium. As used herein, the term “aluminum contaminant” refers to a substance other than the hafnium halide, wherein the substance other than the hafnium halide comprises aluminum. As used herein, the term “iron contaminant” refers to a substance other than the hafnium halide, wherein the substance other than the hafnium halide comprises iron. In some embodiments, the at least one impurity comprises at least one of a titanium halide, a titanium oxide, a titanium nitride, a titanium-ligand complex, a chromium halide, a chromium oxide, a chromium nitride, a chromium-ligand complex, an aluminum halide, an aluminum oxide, an aluminum nitride, an aluminum-ligand complex, an iron halide, an iron oxide, an iron nitride, an iron-ligand complex, or any combination thereof.

The solid reagent may comprise at least 1 ppm of the at least one impurity. For example, in some embodiments, the solid reagent comprises 1 ppm to 1000 ppm of the at least one impurity, or any range or subrange between 1 ppm and 1000 ppm. In some embodiments, the solid reagent comprises 1 ppm to 900 ppm, 1 ppm to 800 ppm, 1 ppm to 700 ppm, 1 ppm to 600 ppm, 1 ppm to 500 ppm, 1 ppm to 400 ppm, 1 ppm to 300 ppm, 1 ppm to 200 ppm, 1 ppm to 100 ppm, 1 ppm to 90 ppm, 1 ppm to 80 ppm, 1 ppm to 70 ppm, 1 ppm to 60 ppm, 1 ppm to 50 ppm, 1 ppm to 40 ppm, 1 ppm to 30 ppm, 1 ppm to 20 ppm, 1 ppm to 10 ppm, 100 ppm to 1000 ppm, 200 ppm to 1000 ppm, 300 ppm to 1000 ppm, 400 ppm to 1000 ppm, 500 ppm to 1000 ppm, 600 ppm to 1000 ppm, 700 ppm to 1000 ppm, 800 ppm to 1000 ppm, 900 ppm to 1000 ppm, 10 ppm to 100 ppm, 20 ppm to 100 ppm, 30 ppm to 100 ppm, 40 ppm to 100 ppm, 50 ppm to 100 ppm, 60 ppm to 100 ppm, 70 ppm to 100 ppm, 80 ppm to 100 ppm, or 90 ppm to 100 ppm of the at least one impurity.

The first vessel may be configured to contain the solid reagent. In some embodiments, the first vessel has at least one of at least one inlet, at least one outlet, or any combination thereof. In some embodiments, the first vessel has an outlet configured to be in fluid communication with a second vessel, which is discussed below.

The first vessel may be configured to control temperature. The temperature of the first vessel may be controlled in any suitable manner. In some embodiments, a thermal jacket for heating and/or cooling is employed around the first vessel. In some embodiments, a ribbon heater is wound around the first vessel. In some embodiments, a block heater having a shape covering at least a major portion of the external surface of the first vessel is employed to heat the first vessel. In some embodiments, a resistive heater is employed to heat the first vessel. In some embodiments, a lamp heater is employed to heat the first vessel. In some embodiments, a heat transfer fluid at elevated temperature may be contacted with the exterior surface of the first vessel, to effect heating and/or cooling thereof. In some embodiments, the heating is conducted by infrared or other radiant energy being impinged upon the first vessel. In some embodiments, the first vessel is cooled by a fluid, a fan, a direct thermoelectric device, or any combination thereof. It is to be appreciated that other heating and/or cooling devices and assemblies, and other configurations and arrangements of the heater and/or cooler may be employed herein without departing from the scope of this disclosure.

The first vessel may be configured to control pressure. The pressure of the first vessel may be controlled in any suitable manner. In some embodiments, a gas inlet line is fluidly coupled to the first vessel. The gas inlet line may be configured to supply a pressurizing gas from a pressurizing gas source to the first vessel. Control of the pressurizing gas into the first vessel may be achieved by at least one of pressure regulators, needle valves, mass flow controllers, downstream pressure controllers, or any combination thereof. In some embodiments, the pressurizing gas comprises an inert gas. In some embodiments, the inert gas comprises at least one of helium, argon, nitrogen, or any combination thereof. In some embodiments, a vacuum line is provided in fluid communication with the first vessel. The vacuum line may be configured to apply a vacuum to the first vessel. In some embodiments, the pumping speed is controlled by butterfly valves. It will be appreciated that other mechanisms for controlling the pressure of the first vessel may be employed herein without departing from the scope of this disclosure.

In some embodiments, the method of purification 100 comprises vaporizing 104 at least a portion of the solid reagent to produce a first vapor comprising a hafnium halide vapor and at least one impurity vapor.

The vaporizing 104 may comprise applying at least one condition sufficient to vaporize at least a portion of the solid reagent. The at least one condition may be applied to at least one of the first vessel, the solid reagent, or any combination thereof. In some embodiments, the vaporizing 104 comprises heating the first vessel and/or solid reagent at or to a temperature sufficient to vaporize at least a portion of the solid reagent. In some embodiments, the vaporizing 104 comprises cooling the first vessel and/or solid reagent at or to a temperature sufficient to vaporize at least a portion of the solid reagent. In some embodiments, the vaporizing 104 comprises pressurizing the first vessel at or to a pressure sufficient to vaporize at least a portion of the solid reagent. In some embodiments, the vaporizing 104 comprises depressurizing the first vessel at or to a pressure sufficient to vaporize at least a portion of the solid reagent. In some embodiments, the vaporizing 104 comprises supplying or flowing an inert gas to the first vessel.

The vaporizing 104 may comprise heating the first vessel and/or solid reagent. For example, in some embodiments, vaporizing 104 at least a portion of the solid reagent comprises heating the first vessel and/or solid reagent to a temperature of 50° C. to 200° C., or any range or subrange between 50° C. and 200° C. In some embodiments, vaporizing 104 at least a portion of the solid reagent comprises heating the first vessel and/or solid reagent to a temperature of 50° C. to 190° C., 50° C. to 180° C., 50° C. to 170° C., 50° C. to 160° C., 50° C. to 150° C., 50° C. to 140° C., 50° C. to 130° C., 50° C. to 120° C., 50° C. to 110° C., 50° C. to 100° C., 50° C. to 90° C., 50° C. to 80° C., 50° C. to 70° C., 50° C. to 60° C., 60° C. to 200° C., 70° C. to 200° C., 80° C. to 200° C., 90° C. to 200° C., 100° C. to 200° C., 110° C. to 200° C., 120° C. to 200° C., 130° C. to 200° C., 140° C. to 200° C., 150° C. to 200° C., 160° C. to 200° C., 170° C. to 200° C., 180° C. to 200° C., 190° C. to 200° C., 90° C. to 140° C., 100° C. to 140° C., 110° C. to 140° C., 120° C. to 140° C., 130° C. to 140° C., 90° C. to 130° C., 90° C. to 120° C., 90° C. to 110° C., or 90° C. to 100° C.

The vaporizing 104 may comprise pressurizing or depressurizing the first vessel. For example, in some embodiments, vaporizing 104 at least a portion of the solid reagent comprises pressurizing or depressurizing the first vessel to a pressure of 0.01 Torr to 100 Torr, or any range or subrange between 0.01 Torr and 100 Torr. In some embodiments, the pressure is a pressure in a range of 0.01 Torr to 95 Torr, 0.01 Torr to 90 Torr, 0.01 Torr to 85 Torr, 0.01 Torr to 80 Torr, 0.01 Torr to 75 Torr, 0.01 Torr to 70 Torr, 0.01 Torr to 65 Torr, 0.01 Torr to 60 Torr, 0.01 Torr to 55 Torr, 0.01 Torr to 50 Torr, 0.01 Torr to 45 Torr, 0.01 Torr to 40 Torr, 0.01 Torr to 35 Torr, 0.01 Torr to 30 Torr, 0.01 Torr to 25 Torr, 0.01 Torr to 20 Torr, 0.01 Torr to 15 Torr, 0.01 Torr to 10 Torr, 0.01 Torr to 5 Torr, 0.01 Torr to 1 Torr, 0.01 Torr to 0.1 Torr, 0.1 Torr to 100 Torr, 1 Torr to 100 Torr, 5 Torr to 100 Torr, 10 Torr to 100 Torr, 15 Torr to 100 Torr, 20 Torr to 100 Torr, 25 Torr to 100 Torr, 30 Torr to 100 Torr, 35 Torr to 100 Torr, 40 Torr to 100 Torr, 45 Torr to 100 Torr, 50 Torr to 100 Torr, 55 Torr to 100 Torr, 60 Torr to 100 Torr, 65 Torr to 100 Torr, 70 Torr to 100 Torr, 75 Torr to 100 Torr, 80 Torr to 100 Torr, 85 Torr to 100 Torr, 90 Torr to 100 Torr, or 95 Torr to 100 Torr.

The vaporizing 104 may be sufficient to vaporize at least a portion of the solid reagent. In some embodiments, the vaporizing 104 may be sufficient to vaporize 1% to 99% (or any range or subrange between 1% and 99%) by weight of the solid reagent based on a total initial weight of the solid reagent. As used herein, the term “total initial weight of the solid reagent” refers to the total weight of the solid reagent prior to vaporizing 104. For example, in some embodiments, the vaporizing 104 may be sufficient to vaporize 1% to 95%, 1% to 90%, 1% to 80%, 1% to 70%, 1% to 60%, 1% to 50%, 1% to 40%, 1% to 30%, 1% to 20%, 1% to 10%, 10% to 99%, 20% to 99%, 30% to 99%, 40% to 99%, 50% to 99%, 60% to 99%, 70% to 99%, 80% to 99%, 90% to 99%, or 95% to 99% by weight of the solid reagent based on the total initial weight of the solid reagent. In some embodiments, the vaporizing may be sufficient to vaporize the solid reagent in its entirety.

The first vapor may comprise a hafnium halide vapor. The hafnium halide vapor may comprise at least one of a hafnium (IV) halide vapor, a hafnium (III) halide vapor, or any combination thereof. For example, in some embodiments, the hafnium halide vapor comprises at least one of hafnium (IV) chloride (HfCl₄) vapor, hafnium (IV) bromide (HfBr₄) vapor, hafnium (IV) iodide (Hfl₄) vapor, hafnium (IV) fluoride (HfF₄) vapor, hafnium (III) chloride (HfCl₃) vapor, hafnium (III) bromide (HfBr₃) vapor, hafnium (III) iodide (Hfl₃) vapor, hafnium (III) fluoride (HfF₃) vapor, or any combination thereof.

The first vapor may comprise at least one impurity vapor. The at least one impurity vapor may comprise at least one of a titanium contaminant vapor, a chromium contaminant vapor, an aluminum contaminant vapor, an iron contaminant vapor, or any combination thereof. In some embodiments, the at least one impurity vapor comprises at least one of a titanium halide vapor, a titanium oxide vapor, a titanium nitride vapor, a titanium-ligand complex vapor, a chromium halide vapor, a chromium oxide vapor, a chromium nitride vapor, a chromium-ligand complex vapor, an aluminum halide vapor, an aluminum oxide vapor, an aluminum nitride vapor, an aluminum-ligand complex vapor, an iron halide vapor, an iron oxide vapor, an iron nitride vapor, an iron-ligand complex vapor, or any combination thereof.

The first vapor may comprise 1% to 99% by volume of the hafnium halide vapor based on a total volume of the first vapor, or any range or subrange between 1% and 99% by volume of the hafnium halide vapor. In some embodiments, the first vapor may comprise 1% to 90%, 1% to 80%, 1% to 70%, 1% to 60%, 1% to 50%, 1% to 40%, 1% to 30%, 1% to 20%, 1% to 10%, 10% to 99%, 20% to 99%, 30% to 99%, 40% to 99%, 50% to 99%, 60% to 99%, 70% to 99%, 80% to 99%, or 90% to 99% by volume of the hafnium halide vapor based on the total volume of the first vapor.

The first vapor may comprise 1% to 99% by volume of the at least one impurity vapor based on the total volume of the first vapor, or any range or subrange between 1% and 99% by volume of the at least one impurity vapor. In some embodiments, the first vapor may comprise 1% to 90%, 1% to 80%, 1% to 70%, 1% to 60%, 1% to 50%, 1% to 40%, 1% to 30%, 1% to 20%, 1% to 10%, 10% to 99%, 20% to 99%, 30% to 99%, 40% to 99%, 50% to 99%, 60% to 99%, 70% to 99%, 80% to 99%, or 90% to 99% by volume of the at least one impurity vapor based on the total volume of the first vapor.

In some embodiments, the method of purification 100 comprises flowing 106 at least a portion of the hafnium halide vapor and at least a portion of the at least one impurity vapor to a second vessel.

The hafnium halide vapor and the at least one impurity vapor may be flowed from the first vessel to the second vessel via the outlet of the first vessel. The outlet of the first vessel may be provided in fluid communication with the second vessel via a gas line or other similar fluid line, piping, or conduit. In some embodiments, the flowing 106 comprises conveying at least a portion of the hafnium halide vapor and at least a portion of the at least one impurity vapor to the second vessel. In some embodiments, the flowing 106 comprises pumping at least a portion of the hafnium halide vapor and at least a portion of the at least one impurity vapor to the second vessel. In some embodiments, the flowing 106 comprises releasing at least a portion of the hafnium halide vapor and at least a portion of the at least one impurity vapor to the second vessel. In some embodiments, the flowing 106 comprises conveying at least a portion of the hafnium halide vapor and at least a portion of the at least one impurity vapor to the second vessel.

The second vessel may be configured to control temperature. The temperature of the second vessel may be controlled in any suitable manner. In some embodiments, a thermal jacket for heating and/or cooling is employed around the second vessel. In some embodiments, a ribbon heater is wound around the second vessel. In some embodiments, a block heater having a shape covering at least a major portion of the external surface of the second vessel is employed to heat the second vessel. In some embodiments, a resistive heater is employed to heat the second vessel. In some embodiments, a lamp heater is employed to heat the second vessel. In some embodiments, a heat transfer fluid at elevated temperature may be contacted with the exterior surface of the second vessel, to effect heating and/or cooling thereof. In some embodiments, the heating is conducted by infrared or other radiant energy being impinged on the second vessel. In some embodiments, the second vessel is cooled by a fluid, a fan, a direct thermoelectric device, or any combination thereof. It is to be appreciated that other heating and/or cooling devices and assemblies, and other configurations and arrangements of the heater and/or cooler may be employed herein without departing from the scope of this disclosure.

The second vessel may be configured to control pressure. The pressure of the second vessel may be controlled in any suitable manner. In some embodiments, a gas inlet line is provided in fluid communication with the second vessel. The gas inlet line may be configured to supply a pressurizing gas from a pressurizing gas source to the second vessel. Control of the pressurizing gas into the second vessel may be achieved by at least one of pressure regulators, needle valves, mass flow controllers, downstream pressure controllers, or any combination thereof. In some embodiments, the pressurizing gas comprises an inert gas. In some embodiments, the inert gas comprises at least one of helium, argon, nitrogen, or any combination thereof. In some embodiments, a vacuum line is fluidly coupled to the second vessel. The vacuum line may be configured to apply a vacuum to the second vessel. In some embodiments, the pumping speed is controlled by butterfly valves. It will be appreciated that other mechanisms for controlling the pressure of the second vessel may be employed herein without departing from the scope of this disclosure.

In some embodiments, the method of purification 100 comprises condensing 108 at least a portion of the hafnium halide vapor in the second vessel to separate at least a portion of the hafnium halide vapor from the at least one impurity vapor.

The condensing 108 may comprise applying at least one condition sufficient to condense at least a portion of the hafnium halide vapor in the second vessel. The at least one condition may be applied to at least one of the second vessel, the hafnium halide vapor, the at least one impurity vapor, or any combination thereof. In some embodiments, the condensing comprises cooling the second vessel and/or the hafnium halide vapor at or to a temperature sufficient to condense at least a portion of the hafnium halide vapor in the second vessel. In some embodiments, the condensing 108 comprises pressurizing the second vessel at or to a pressure sufficient to condense at least a portion of the hafnium halide vapor in the second vessel. In some embodiments, the condensing 108 comprises depressurizing the second vessel at or to a pressure sufficient to condense at least a portion of the hafnium halide vapor in the second vessel.

The condensing 108 may comprise cooling the second vessel and/or hafnium halide vapor. In some embodiments, condensing 108 at least a portion of the hafnium halide vapor in the second vessel comprises cooling the second vessel at or to a temperature of −50° C. to 200° C., or any range or subrange between −50° C. and 200° C. In some embodiments, condensing 108 at least a portion of the hafnium halide vapor in the second vessel comprises cooling the second vessel at or to a temperature of −50° C. to 20° C., or any range or subrange between −50° C. and 20° C. For example, in some embodiments, the condensing 108 at least a portion of the hafnium halide vapor in the second vessel comprises cooling the second vessel to a temperature of −50° C. to 200° C., −40° C. to 200° C., −30° C. to 200° C., −20° C. to 200° C., −10° C. to 200° C., 0° C. to 200° C., 10° C. to 200° C., 20° C. to 200° C., 30° C. to 200° C., 40° C. to 200° C., 50° C. to 200° C., 60° C. to 200° C., 70° C. to 200° C., 80° C. to 200° C., 90° C. to 200° C., 100° C. to 200° C., 110° C. to 200° C., 120° C. to 200° C., 130° C. to 200° C., 140° C. to 200° C., 150° C. to 200° C., 160° C. to 200° C., 170° C. to 200° C., 180° C. to 200° C., 190° C. to 200° C., −50° C. to 10° C., −50° C. to 0° C., −50° C. to −10° C., −50° C. to −20° C., −50° C. to −30° C., or −50° C. to −40° C. In some embodiments, the temperature is a temperature sufficient to cause the hafnium halide precursor vapor to condense, without condensing at least a portion of the at least one impurity vapor.

The condensing 108 may comprise pressurizing or depressurizing the second vessel. For example, in some embodiments, condensing 108 at least a portion of the hafnium halide vapor comprises pressurizing or depressurizing the second vessel to a pressure of 0.01 Torr to 100 Torr, or any range or subrange between 0.01 Torr and 100 Torr. In some embodiments, the pressure is a pressure in a range of 0.01 Torr to 95 Torr, 0.01 Torr to 90 Torr, 0.01 Torr to 85 Torr, 0.01 Torr to 80 Torr, 0.01 Torr to 75 Torr, 0.01 Torr to 70 Torr, 0.01 Torr to 65 Torr, 0.01 Torr to 60 Torr, 0.01 Torr to 55 Torr, 0.01 Torr to 50 Torr, 0.01 Torr to 45 Torr, 0.01 Torr to 40 Torr, 0.01 Torr to 35 Torr, 0.01 Torr to 30 Torr, 0.01 Torr to 25 Torr, 0.01 Torr to 20 Torr, 0.01 Torr to 15 Torr, 0.01 Torr to 10 Torr, 0.01 Torr to 5 Torr, 0.01 Torr to 1 Torr, 0.01 Torr to 0.1 Torr, 0.1 Torr to 100 Torr, 1 Torr to 100 Torr, 5 Torr to 100 Torr, 10 Torr to 100 Torr, 15 Torr to 100 Torr, 20 Torr to 100 Torr, 25 Torr to 100 Torr, 30 Torr to 100 Torr, 35 Torr to 100 Torr, 40 Torr to 100 Torr, 45 Torr to 100 Torr, 50 Torr to 100 Torr, 55 Torr to 100 Torr, 60 Torr to 100 Torr, 65 Torr to 100 Torr, 70 Torr to 100 Torr, 75 Torr to 100 Torr, 80 Torr to 100 Torr, 85 Torr to 100 Torr, 90 Torr to 100 Torr, or 95 Torr to 100 Torr. In some embodiments, the pressure is a pressure sufficient to cause the hafnium halide precursor vapor to condense, without condensing at least a portion of the at least one impurity vapor.

In some embodiments, the method of purification 100 comprises removing 110 at least a portion of the impurity vapor from the second vessel to obtain a hafnium halide precursor. In one embodiment, removing 110 at least a portion of the impurity vapor from the second vessel includes flowing the impurity vapor into a trap.

Once the hafnium halide vapor is condensed, the removing 110 of at least a portion of the at least one impurity vapor from the second vessel may be sufficient to separate at least a portion of the at least one impurity vapor from the hafnium halide precursor. In some embodiments, the removing 110 comprises removing at least a portion of the at least one impurity vapor from the second vessel via an outlet of the second vessel. In some embodiments, the removing 110 comprises discharging at least a portion of the at least one impurity vapor from the second vessel via an outlet of the second vessel. In some embodiments, the removing 110 comprises evacuating at least a portion of the at least one impurity vapor from the second vessel via an outlet of the second vessel. In some embodiments, the removing 110 comprises releasing at least a portion of the at least one impurity vapor from the second vessel via an outlet of the second vessel. In some embodiments, the outlet of the second vessel is provided in fluid communication with at least one of a gas discharge line, a vacuum line, or other similar gas line suitable for removing at least a portion of the at least one impurity vapor from the second vessel.

The resulting hafnium halide precursor may have greater than 0 ppm to 1 ppm of the at least one impurity, or any range or subrange between greater than 0 ppm and 1 ppm. In some embodiments, the hafnium halide precursor comprises 0.001 ppm to 1 ppm, 0.002 ppm to 1 ppm, 0.003 ppm to 1 ppm, 0.004 ppm to 1 ppm, 0.005 ppm to 1 ppm, 0.006 ppm to 1 ppm, 0.007 ppm to 1 ppm, 0.008 ppm to 1 ppm, 0.009 ppm to 1 ppm, 0.01 ppm to 1 ppm, 0.02 ppm to 1 ppm, 0.03 ppm to 1 ppm, 0.04 ppm to 1 ppm, 0.05 ppm to 1 ppm, 0.06 ppm to 1 ppm, 0.07 ppm to 1 ppm, 0.08 ppm to 1 ppm, 0.09 ppm to 1 ppm, 0.1 ppm to 1 ppm, 0.2 ppm to 1 ppm, 0.3 ppm to 1 ppm, 0.4 ppm to 1 ppm, 0.5 ppm to 1 ppm, 0.6 ppm to 1 ppm, 0.7 ppm to 1 ppm, 0.8 ppm to 1 ppm, or 0.9 ppm to 1 ppm of the at least one impurity. In some embodiments, the hafnium halide precursor comprises 0.001 ppm to 0.9 ppm, 0.001 ppm to 0.8 ppm, 0.001 ppm to 0.7 ppm, 0.001 ppm to 0.6 ppm, 0.001 ppm to 0.5 ppm, 0.001 ppm to 0.4 ppm, 0.001 ppm to 0.3 ppm, 0.001 ppm to 0.2 ppm, 0.001 ppm to 0.1 ppm, 0.001 ppm to 0.09 ppm, 0.001 ppm to 0.08 ppm, 0.001 ppm to 0.07 ppm, 0.001 ppm to 0.06 ppm, 0.001 ppm to 0.05 ppm, 0.001 ppm to 0.04 ppm, 0.001 ppm to 0.03 ppm, 0.001 ppm to 0.02 ppm, 0.001 ppm to 0.01 ppm, 0.001 ppm to 0.009 ppm, 0.001 ppm to 0.008 ppm, 0.001 ppm to 0.007 ppm, 0.001 ppm to 0.006 ppm, 0.001 ppm to 0.005 ppm, 0.001 ppm to 0.004 ppm, 0.001 ppm to 0.003 ppm, or 0.001 ppm to 0.002 ppm of the at least one impurity. In some embodiments, the hafnium halide precursor is present in at least one of a solid phase, a vapor phase, a gas phase, a liquid phase, or any combination thereof. In some embodiments, the hafnium halide precursor is not present in at least one of a vapor phase, a gas phase, a liquid phase, or any combination thereof.

Some embodiments relate to a system. The system may comprise a precursor vessel. In some embodiments, the precursor vessel comprises a hafnium halide precursor. In some embodiments, the hafnium halide precursor comprises less than 1 ppm of at least one impurity. In some embodiments, the system comprises a vapor deposition apparatus. The vapor deposition apparatus may be provided in fluid communication with the precursor vessel. For example, in some embodiments, the vapor deposition apparatus is provided in fluid communication with an outlet of the precursor vessel.

In some embodiments, the hafnium halide precursor has sufficiently low impurity levels such that, when the hafnium halide precursor is vaporized to a hafnium halide vapor, the hafnium halide vapor is supplied to the vapor deposition apparatus at a delivery rate that is within 5%, 4%, 3%, 2%, or 1% of an initial delivery rate (e.g., the delivery rate of the hafnium halide vapor initially being supplied to the vapor deposition apparatus). In some embodiments, the hafnium halide precursor has sufficiently low impurity levels such that, when supplied to a tool used in semiconductor fabrication or other similar processes, the hafnium halide precursor, upon being vaporized, is supplied to the tool at a controllable constant flow rate, without appreciable spikes or variations in flow rate.

The hafnium halide precursor may have greater than 0 ppm to 1 ppm of the at least one impurity, or any range or subrange between greater than 0 ppm and 1 ppm. In some embodiments, the hafnium halide precursor comprises 0.001 ppm to 1 ppm, 0.002 ppm to 1 ppm, 0.003 ppm to 1 ppm, 0.004 ppm to 1 ppm, 0.005 ppm to 1 ppm, 0.006 ppm to 1 ppm, 0.007 ppm to 1 ppm, 0.008 ppm to 1 ppm, 0.009 ppm to 1 ppm, 0.01 ppm to 1 ppm, 0.02 ppm to 1 ppm, 0.03 ppm to 1 ppm, 0.04 ppm to 1 ppm, 0.05 ppm to 1 ppm, 0.06 ppm to 1 ppm, 0.07 ppm to 1 ppm, 0.08 ppm to 1 ppm, 0.09 ppm to 1 ppm, 0.1 ppm to 1 ppm, 0.2 ppm to 1 ppm, 0.3 ppm to 1 ppm, 0.4 ppm to 1 ppm, 0.5 ppm to 1 ppm, 0.6 ppm to 1 ppm, 0.7 ppm to 1 ppm, 0.8 ppm to 1 ppm, or 0.9 ppm to 1 ppm of the at least one impurity. In some embodiments, the hafnium halide precursor comprises 0.001 ppm to 0.9 ppm, 0.001 ppm to 0.8 ppm, 0.001 ppm to 0.7 ppm, 0.001 ppm to 0.6 ppm, 0.001 ppm to 0.5 ppm, 0.001 ppm to 0.4 ppm, 0.001 ppm to 0.3 ppm, 0.001 ppm to 0.2 ppm, 0.001 ppm to 0.1 ppm, 0.001 ppm to 0.09 ppm, 0.001 ppm to 0.08 ppm, 0.001 ppm to 0.07 ppm, 0.001 ppm to 0.06 ppm, 0.001 ppm to 0.05 ppm, 0.001 ppm to 0.04 ppm, 0.001 ppm to 0.03 ppm, 0.001 ppm to 0.02 ppm, 0.001 ppm to 0.01 ppm, 0.001 ppm to 0.009 ppm, 0.001 ppm to 0.008 ppm, 0.001 ppm to 0.007 ppm, 0.001 ppm to 0.006 ppm, 0.001 ppm to 0.005 ppm, 0.001 ppm to 0.004 ppm, 0.001 ppm to 0.003 ppm, or 0.001 ppm to 0.002 ppm of the at least one impurity. In some embodiments, the hafnium halide precursor is present in at least one of a solid phase, a vapor phase, a gas phase, a liquid phase, or any combination thereof. In some embodiments, the hafnium halide precursor is not present in at least one of a vapor phase, a gas phase, a liquid phase, or any combination thereof.

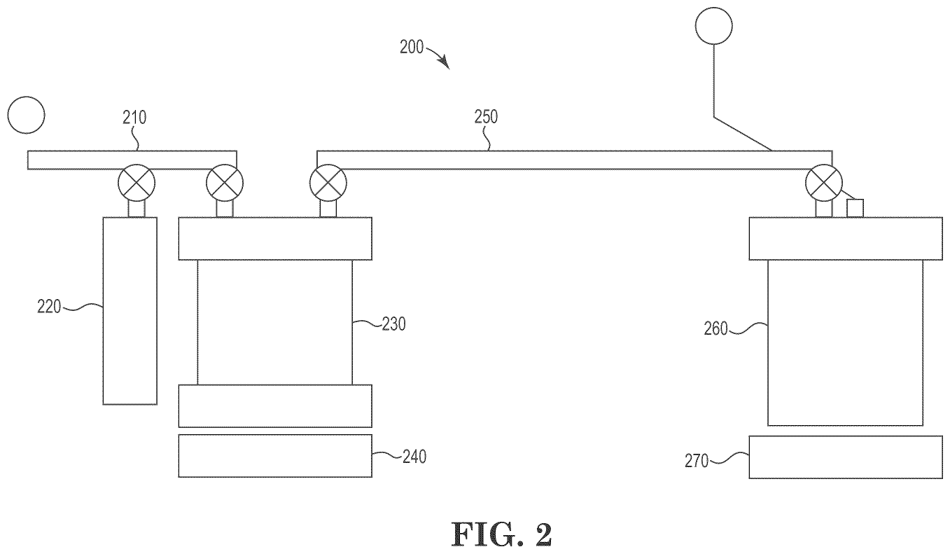

FIG. 2 is an embodiment of a system 200 for purification of hafnium halide precursor. The system 200 includes a first piping 250, a first vessel 260, a first scale 270, a second piping 210, a second vessel 230, a second scale 240, and a trap 220. The system 200 may include a number of valves, for example, as shown in FIG. 2.

The system 200 may be used to reduce the amount of titanium impurities in hafnium halide precursor. In an embodiment, components of the system 200 are stainless steel, e.g., 304 or 316L stainless steel.

The first vessel 260 contains the precursor material to be purified. The first vessel 260 rests on first scale 270. The first vessel is connected to the first piping 250 to the second vessel 230. The first vessel 260 may include an integrated heater. In some embodiments, the first vessel 260 has a heater in thermal communication with the first vessel 260 to heat the first vessel 260 to a desired temperature.

The first scale 270 supports the first vessel 260 and provides the weight of the first vessel 260. The weight of the first vessel 260 may be used to monitor the amount of precursor material in the first vessel 260. This allows monitoring of the processing of the precursor material in the first vessel 260.

The first piping 250 connects the first vessel 260 to the second vessel 230. Heated precursor may travel from the first vessel 260 to the second vessel 230 through the first piping 250. In some embodiments, the heated precursor travels as a vapor through the first piping 250. The first piping 250 may be heated. For example, the first piping 250 may be wrapped with heating tape.

The second vessel 230 receives vapor from the first piping 250 and condenses the precursor vapor back into a solid. In some embodiments, the second vessel 230 is heated. The second vessel 230 may be heated to a lower temperature than the first vessel 260. In an embodiment, the second vessel 230 is maintained at room temperature. In another embodiment, the second vessel 230 is cooled. The second vessel rests on the second scale 240. In some embodiments, the outlet of the second vessel 230 is provided in fluid communication with second piping 210, a vacuum line, or other similar gas line suitable for removing at least a portion of the at least one impurity vapor from the second vessel 230. The second piping 210 may be connected to the trap 220 to capture impurity vapor.

The second scale 240 serves to monitor the amount of precursor material that has accumulated in the second vessel 230 during the purification process. The second scale 240 may be used in conjunction with the first scale 270 to monitor the process and determine when to stop the purification process. In some embodiments, a majority of the precursor material in the first vessel 260 is transferred to the second vessel 230 as verified by the first scale 270 and the second scale 240.

The trap 220 is used to control the presence of impurities flowing into the second vessel 230. The trap 220 is connected to the second vessel by the second piping 210.

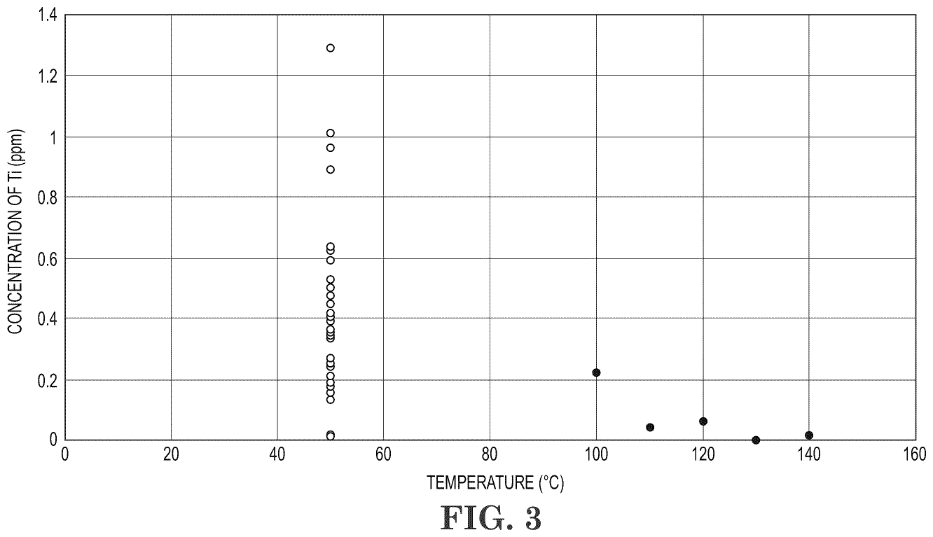

FIG. 3 is a chart showing purity levels by temperature. As can be seen, the batches produced at 50° C. include a wide range of titanium levels including examples above 1 ppm. In contrast, those produced by the described method at temperatures of at least 100° C. exhibit much lower levels of titanium impurities.

### ASPECTS

Various Aspects are described below. It is to be understood that any one or more of the features recited in the following Aspect(s) can be combined with any one or more other Aspect(s).

Aspect 1. A system comprising:
a precursor vessel comprising a solid HfCl₄ precursor,
   wherein the solid HfCl₄ precursor comprises less than 1 ppm of a titanium contaminant.

Aspect 2. The system according to Aspect 1, wherein the solid HfCl₄ precursor comprises greater than 0 ppm to 1 ppm of the titanium contaminant.

Aspect 3. The system according to any one of Aspects 1-2, wherein the solid HfCl₄ precursor comprises 0.001 ppm to 1 ppm of the titanium contaminant.

Aspect 4. The system according to any one of Aspects 1-3, wherein the solid HfCl₄ precursor comprises 0.01 ppm to 1 ppm of the titanium contaminant.

Aspect 5. The system according to any one of Aspects 1-4, wherein the titanium contaminant comprises at least one of a titanium halide, a titanium oxide, a titanium nitride, a titanium-ligand complex, or any combination thereof.

Aspect 6. The system according to any one of Aspects 1-5, further comprising:
a vapor deposition apparatus,
   wherein the vapor deposition apparatus is fluidly coupled to an outlet of the precursor vessel.

Aspect 7. The system according to Aspect 6, wherein, when the solid HfCl₄ precursor is vaporized to an HfCl₄ vapor, the HfCl₄ vapor is supplied to the vapor deposition apparatus at a delivery rate that is within 5% of an initial delivery rate.

Aspect 8. The system according to any one of Aspects 1-7, wherein the solid HfCl₄ precursor further comprises at least one of a chromium contaminant, an aluminum contaminant, an iron contaminant, or any combination thereof.

Aspect 9. A method comprising:
obtaining a first vessel comprising a solid reagent, the solid reagent comprising HfCl₄ and at least one impurity;
vaporizing at least a portion of the solid reagent to produce a first vapor comprising at least one of a HfCl₄ vapor, at least one impurity vapor, or any combination thereof;
flowing at least a portion of the HfCl₄ vapor and at least a portion of the impurity vapor to a second vessel;
condensing at least a portion of the HfCl₄ vapor in the second vessel to separate the HfCl₄ from the impurity vapor; and
removing at least a portion of the impurity vapor from the second vessel to obtain a HfCl₄ precursor.

Aspect 10. The method according to Aspect 9, wherein the solid reagent comprises at least 1 ppm of a titanium contaminant.

Aspect 11. The method according to any one of Aspects 9-10, wherein the solid reagent comprises 1 ppm to 100 ppm of a titanium contaminant.

Aspect 12. The method according to any one of Aspects 9-11, wherein the solid reagent comprises 1 ppm to 1000 ppm of a titanium contaminant.

Aspect 13. The method according to any one of Aspects 9-12, wherein the at least one impurity comprises at least one of a titanium contaminant, a chromium contaminant, an aluminum contaminant, an iron contaminant, or any combination thereof.

Aspect 14. The method according to any one of Aspects 9-13, wherein the at least one impurity comprises at least one of a titanium halide, a titanium oxide, a titanium nitride, a titanium-ligand complex, or any combination thereof.

Aspect 15. The method according to any one of Aspects 9-14, wherein the vaporizing comprises heating the first vessel to a temperature of at least 50° C.

Aspect 16. The method according to any one of Aspects 9-15, wherein the vaporizing comprises heating the first vessel to a temperature of 90° C. to 140° C.

Aspect 17. The method according to any one of Aspects 9-16, wherein the condensing comprises cooling the second vessel to a temperature of less than 20° C.

Aspect 18. The method according to any one of Aspects 9-17, wherein the HfCl₄ precursor comprises greater than 0 ppm to 1 ppm of a titanium contaminant.

Aspect 19. The method according to any one of Aspects 9-18, wherein the HfCl₄ precursor comprises 0.001 ppm to 1 ppm of a titanium contaminant.

Aspect 20. The method according to any one of Aspects 9-19, wherein the HfCl₄ precursor comprises 0. 01 ppm to 1 ppm of a titanium contaminant.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. A system comprising:
a precursor vessel comprising a solid HfCl₄ precursor,
wherein the solid HfCl₄ precursor comprises less than 1 ppm of a titanium contaminant.

2. The system of claim 1, wherein the solid HfCl₄ precursor comprises greater than 0 ppm to 1 ppm of the titanium contaminant.

3. The system of claim 1, wherein the solid HfCl₄ precursor comprises 0.001 ppm to 1 ppm of the titanium contaminant.

4. The system of claim 1, wherein the solid HfCl₄ precursor comprises 0.01 ppm to 1 ppm of the titanium contaminant.

5. The system of claim 1, wherein the titanium contaminant comprises at least one of a titanium halide, a titanium oxide, a titanium nitride, a titanium-ligand complex, or any combination thereof.

6. The system of claim 1, further comprising:
a vapor deposition apparatus,
wherein the vapor deposition apparatus is fluidly coupled to an outlet of the precursor vessel.

7. The system of claim 6, wherein, when the solid HfCl₄ precursor is vaporized to an HfCl₄ vapor, the HfCl₄ vapor is supplied to the vapor deposition apparatus at a delivery rate that is within 5% of an initial delivery rate.

8. The system of claim 1, wherein the solid HfCl₄ precursor further comprises at least one of a chromium contaminant, an aluminum contaminant, an iron contaminant, or any combination thereof.

9. A method comprising:
obtaining a first vessel comprising a solid reagent, the solid reagent comprising HfCl₄ and at least one impurity;
vaporizing at least a portion of the solid reagent to produce a first vapor comprising at least one of a HfCl₄ vapor, at least one impurity vapor, or any combination thereof;
flowing at least a portion of the HfCl₄ vapor and at least a portion of the impurity vapor to a second vessel;
condensing at least a portion of the HfCl₄ vapor in the second vessel to separate the HfCl₄ from the impurity vapor; and
removing at least a portion of the impurity vapor from the second vessel to obtain a HfCl₄ precursor.

10. The method of claim 9, wherein the solid reagent comprises at least 1 ppm of a titanium contaminant.

11. The method of claim 9, wherein the solid reagent comprises 1 ppm to 100 ppm of a titanium contaminant.

12. The method of claim 9, wherein the solid reagent comprises 1 ppm to 1000 ppm of a titanium contaminant.

13. The method of claim 9, wherein the at least one impurity comprises at least one of a titanium contaminant, a chromium contaminant, an aluminum contaminant, an iron contaminant, or any combination thereof.

14. The method of claim 9, wherein the at least one impurity comprises at least one of a titanium halide, a titanium oxide, a titanium nitride, a titanium-ligand complex, or any combination thereof.

15. The method of claim 9, wherein the vaporizing comprises heating the first vessel to a temperature of at least 50° C.

16. The method of claim 9, wherein the vaporizing comprises heating the first vessel to a temperature of 90° C. to 140° C.

17. The method of claim 9, wherein the condensing comprises cooling the second vessel to a temperature of less than 20° C.

18. The method of claim 9, wherein the HfCl₄ precursor comprises greater than 0 ppm to 1 ppm of a titanium contaminant.

19. The method of claim 9, wherein the HfCl₄ precursor comprises 0.001 ppm to 1 ppm of a titanium contaminant.

20. The method of claim 9, wherein the HfCl₄ precursor comprises 0.01 ppm to 1 ppm of a titanium contaminant.
